(19) United States
(12) Patent Application Publication
(10) Pub. No.: US 2026/0015760 A1
(43) Pub. Date: Jan. 15, 2026

(54) SINGLE CRYSTAL CATHODE MATERIALS USING MICROWAVE PLASMA PROCESSING

(71) Applicant: 6K Inc., North Andover, MA (US)

(72) Inventors: RICHARD K. HOLMAN, WELLESLEY, MA (US); ADRIAN PULLEN, BOSTON, MA (US); GREGORY M. WROBEL, WEST NEWBURY, MA (US); JOHN COLWELL, DURHAM, NH (US)

(21) Appl. No.: 19/040,742

(22) Filed: Jan. 29, 2025

Related U.S. Application Data
(63) Continuation of application No. 17/577,797, filed on Jan. 18, 2022, now abandoned.
(60) Provisional application No. 63/139,198, filed on Jan. 19, 2021.

(51) Int. Cl. C30B 1/02; C30B 29/22; H01M 4/02; H01M 4/505; H01M 4/525

(52) U.S. Cl. CPC C30B 1/02; C30B 29/22; H01M 4/505; H01M 4/525; H01M 2004/028

(57) ABSTRACT

Disclosed herein are systems and methods for synthesis of submicron-scale or micron-scale single crystal cathode (SCC) material, such as NMC, using a feedstock and microwave plasma processing. Microwave plasma processing of these SCC materials provides a low cost, scalable approach. In some embodiments, advanced SCC materials may be synthesized through microwave plasma processing of feedstock materials, wherein the SCC materials may comprise at least 80% nickel. In some embodiments, the microwave plasma processing may enable synthesis of SCC materials with very short calcination.

### INCORPORATION BY REFERENCE TO ANY PRIORITY APPLICATIONS

This application is a continuation of U.S. patent application Ser. No. 17/577,797, filed Jan. 18, 2022, which claims the priority benefit under 35 U.S.C. § 119 (e) of U.S. Provisional Application No. 63/139,198, filed Jan. 19, 2021, the entire disclosure of which is incorporated herein by reference. Any and all applications for which a foreign or domestic priority claim is identified in the Application Data Sheet as filed with the present application are hereby incorporated by reference under 37 CFR 1.57.

### BACKGROUND

### Field

Some embodiments of the present disclosure are directed to systems and methods for producing or synthesizing single crystal cathode materials from feedstock using microwave plasma processing.

### Description

The nickel content of oxide-based, lithium-ion cathodes has trended steadily upward to enable higher energy density in both portable power and automotive applications. However, stability and reactivity issues have slowed the adoption of NMC 811 in the market. NMC 811 is a cathode composition with 80% nickel, 10% manganese, and 10% cobalt.

High-nickel, transition-metal, oxide cathode materials, such as lithium nickel cobalt manganese oxides (NCM or NMC) and lithium nickel cobalt aluminum oxides (NCA) suffer several modes of failure that derive from their nickel content. Each mode of failure is at least partially due to the comparatively weaker oxygen bonding in the LNO lattice and the greater stability of Ni₂+ ions in the lithium layer.

One failure mode comprises bulk destabilization of the structure in the charged state where oxygen is oxidized and lost, leaving Ni₂+, which migrates from the transition layer into the lithium layer. This failure is a direct result of lithium-loss in the electrochemical cell which, in turn, causes the voltage window to migrate upward and the charge-voltage at the cathode to slowly increase. This is a cycling failure that causes increased resistance to lithium diffusion and a decrease in rate capability.

Another failure mode includes a loss of nickel oxidation state where the ordered, layered structure at grain boundaries gives way to spinel and then NiO. Since lithium diffusion is much poorer in NiO, rate capability is directly impacted. This failure also causes reduced cohesion of the crystalline agglomerate, which promotes cracking of the particle along grain boundaries as crystals expand and contract during cycling. Thus, the loss of rate capability is accompanied by a loss of capacity as grains become internally disconnected.

Yet another failure mode comprises electrolyte instability at the surface of uncoated materials. Here, Ni₄+ oxides serve as catalytic surfaces, which cause gassing and other decomposition pathways for the electrolyte solvent.

While NMC 811 adopted as surface coatings and electrolyte formulations partially address the issues described above, it is expected that single crystal NMC 811 can enable further improvement. Single-crystal cathode materials (SCC) have demonstrated benefits in cycle life, reactivity, and safety through mechanisms that address the failure modes of high-nickel materials. Namely, SCC materials have no vulnerable intraparticle grain boundaries. In addition, SCC grain surfaces have lower surface area and are relatively defect free compared to their polycrystalline counterparts, mitigating some failure modes. Thus, single crystal materials can enable NMC 811 and higher nickel contents, because one or more failure modes are reduced or eliminated.

While SCC morphologies are generally straightforward to produce with nickel content up to LiNi_{0.5}Co_{0.2}Mn_{0.3}O₂ (NMC523) with additional processing, it becomes increasingly difficult and costly as nickel composition is increased beyond 60%. The same structural issues that give rise to electrochemical instability also impede SCC synthesis. Weaker lithium nickel dioxide (LNO) oxygen bonding prohibits the high temperatures required to grow large crystals, such as for Lithium Cobalt Oxide (LCO), because both oxygen and lithium are lost and disordered materials result. To circumvent this issue, practitioners have used fluxes to increase the rate of transition-metal diffusion at lower temperatures. These fluxes can be salts such as NaCl or LiCl or an excess of lithium hydroxide or carbonate. Even with fluxes, intimate contact between the metal oxides and the flux is required to enable large crystals. Fully molten nitrate salt syntheses with significant excess lithium have demonstrated the rapid diffusion required for SCC synthesis at low temperature. More traditional co-precipitated hydroxides have also been demonstrated but must be aggressively ground with the lithium/flux. The heightened transition metal diffusion from fluxing comes at a cost, with hard bricks forming during calcination that must be broken up by aggressive milling. In addition, residual excess lithium/flux must then be removed by washing followed by heat treatment to repair the washing damage. These methods have enabled single crystals of cathode materials up to nickel content of 811 but at considerable processing cost.

Thus, improved systems and methods for synthesizing single crystal lithium-ion cathode materials are needed.

### SUMMARY

For purposes of this summary, certain aspects, advantages, and novel features of the invention are described herein. It is to be understood that not all such advantages necessarily may be achieved in accordance with any particular embodiment of the invention. Thus, for example, those skilled in the art will recognize that the invention may be embodied or carried out in a manner that achieves one advantage or group of advantages as taught herein without necessarily achieving other advantages as may be taught or suggested herein.

Some aspects include a method for synthesizing single-crystal cathode (SCC) powder, the method comprising: providing a solid or aqueous feedstock comprising lithium, nickel, and cobalt; introducing the feedstock into a microwave-generated plasma to produce a solid precursor of SCC comprising lithium nitrate; calcining the pre-SCC product for about 1 hour to about 5 hours at about 800° C. to produce an agglomerated SCC material; and deagglomerating the agglomerated SCC material to produce the SCC powder.

In some embodiments, the SCC powder comprises a lithium nickel cobalt manganese oxide (NMC) powder. In some embodiments, the NMC powder comprises NMC-811. In some embodiments, the NMC powder comprises at least 80% nickel by weight. In some embodiments, the SCC powder comprises lithium nickel cobalt aluminum oxide (NCA) powder. In some embodiments, the NCA powder comprises at least 80% nickel by weight. In some embodiments, the feedstock further comprises manganese. In some embodiments, the feedstock further comprises aluminum. In some embodiments, the feedstock comprises lithium, nickel, and cobalt nitrate or lithium, nickel, and cobalt acetate salts dissolved in water. In some embodiments, the feedstock comprises nickel oxide, manganese oxide, and cobalt oxide.

In some embodiments, the method further comprises spray drying the feedstock prior to introducing the feedstock into the microwave-generated plasma. In some embodiments, the method further comprises adding lithium to the solid product prior to or during calcining the solid product.

In some embodiments, lithium nitrate is located within pores of the pre-SCC product. In some embodiments, the feedstock is introduced to the microwave-generated plasma downstream of the plume of a microwave plasma torch generating the microwave-generated plasma.

Some aspects include a single-crystal cathode (SCC) lithium nickel cobalt manganese oxide (NMC) powder formed by a method comprising: providing a solid or aqueous feedstock comprising lithium, nickel, manganese, and cobalt; introducing the feedstock into a microwave-generated plasma to produce a solid pre-SCC product comprising lithium nitrate; calcining the solid product for about 1 hour to about 5 hours at about 800° C. to produce an agglomerated SCC material; and deagglomerating the agglomerated SCC material to produce the SCC NMC powder.

In some embodiments, the NMC powder comprises NMC-811. In some embodiments, the NMC powder comprises at least 80% nickel by weight. In some embodiments, the feedstock comprises lithium, nickel, and cobalt nitrate salts or lithium, nickel, and cobalt acetate salts dissolved in water. In some embodiments, the feedstock comprises nickel oxide, manganese oxide, and cobalt oxide.

Some aspects include a method for synthesizing single-crystal cathode (SCC) material, the method comprising: providing a solid or liquid feedstock; introducing the feedstock into a microwave-generated plasma to produce a solid precursor of SCC material; and calcining the solid precursor of SCC material to produce an SCC material.

In some embodiments, the SCC material comprises a lithium nickel cobalt manganese oxide (NMC) powder. In some embodiments, the NMC powder comprises NMC-811. In some embodiments, the NMC powder comprises at least 80% nickel by weight.

In some embodiments, the solid precursor of SCC material comprises NMC having a disordered, oxide microstructure. In some embodiments, the solid precursor of SCC material comprises NMC having pores filled with lithium nitrate.

In some embodiments, the SCC material comprises lithium nickel cobalt aluminum oxide (NCA) powder. In some embodiments, the NCA powder comprises at least 80% nickel by weight. In some embodiments, the SCC material comprises a spinel or NaFeO2. In some embodiments, the feedstock comprises manganese, aluminum, magnesium, titanium, zirconium, iron, or sodium.

In some embodiments, the feedstock comprises lithium, nickel, and cobalt nitrate or lithium, nickel, and cobalt acetate salts dissolved in water. In some embodiments, the feedstock comprises a dried feedstock dried using spray drying, dry milling, or blending.

In some embodiments, the SCC material comprises an agglomerated SCC material and the method further comprises deagglomerating the agglomerated SCC material to produce SCC powder.

In some embodiments, the method further comprises adding lithium or lithium salt to the solid precursor of SCC material prior to or during calcining the solid precursor of SCC material.

In some embodiments, lithium nitrate is located within pores of the pre-SCC product. In some embodiments, the solid precursor of SCC material is calcined for about 0.25 hours to about 10 hours at a temperature between about 650° C. and 1000° C.

Some aspects include single-crystal cathode (SCC) material formed by a method comprising: providing a solid or liquid feedstock; introducing the feedstock into a microwave-generated plasma to produce a solid precursor of SCC material; and calcining the solid precursor of SCC material to produce an SCC material.

In some embodiments, the SCC material comprises NMC. In some embodiments, the NMC comprises at least 80% nickel by weight. In some embodiments, the SCC material comprises a spinel or NaFeO2.

### BRIEF DESCRIPTION OF THE DRAWINGS

The drawings are provided to illustrate example embodiments and are not intended to limit the scope of the disclosure. A better understanding of the systems and methods described herein will be appreciated upon reference to the following description in conjunction with the accompanying drawings, wherein:

FIG. 1 illustrates a system schematic of an example microwave plasma processing apparatus according to some embodiments herein.

FIG. 2 illustrates another system schematic an exemplary microwave plasma processing apparatus according to some embodiments herein.

FIG. 3 illustrates examples of chemistries and size flexibility of plasma processing systems for lithium ion/solid state chemistries according to some embodiments herein.

FIG. 4 illustrates a microscopic image of an example NMC powder morphology synthesized according to the embodiments herein.

FIG. 5 illustrates an example flowchart of a process for producing a SCC material according to some embodiments described herein.

FIG. 6 illustrates a microscopic image of another example NMC powder morphology synthesized according to the embodiments herein.

FIG. 7 illustrates an example flowchart of another process for producing a SCC material according to some embodiments described herein.

FIG. 8 illustrates a microscopic image of another example NMC powder morphology synthesized according to the embodiments herein.

FIG. 9 illustrates an example flowchart of another process for producing a SCC material according to some embodiments described herein.

FIG. 10 illustrates a microscopic image of another example NMC powder morphology synthesized according to the embodiments herein.

### DETAILED DESCRIPTION

Although certain preferred embodiments and examples are disclosed below, inventive subject matter extends beyond the specifically disclosed embodiments to other alternative embodiments and/or uses and to modifications and equivalents thereof. Thus, the scope of the claims appended hereto is not limited by any of the particular embodiments described below. For example, in any method or process disclosed herein, the acts or operations of the method or process may be performed in any suitable sequence and are not necessarily limited to any particular disclosed sequence. Various operations may be described as multiple discrete operations in turn, in a manner that may be helpful in understanding certain embodiments; however, the order of description should not be construed to imply that these operations are order dependent. Additionally, the structures, systems, and/or devices described herein may be embodied as integrated components or as separate components. For purposes of comparing various embodiments, certain aspects and advantages of these embodiments are described. Not necessarily all such aspects or advantages are achieved by any particular embodiment. Thus, for example, various embodiments may be carried out in a manner that achieves or optimizes one advantage or group of advantages as taught herein without necessarily achieving other aspects or advantages as may also be taught or suggested herein.

Certain exemplary embodiments will now be described to provide an overall understanding of the principles of the structure, function, manufacture, and use of the devices and methods disclosed herein. One or more examples of these embodiments are illustrated in the accompanying drawings. Those skilled in the art will understand that the devices and methods specifically described herein and illustrated in the accompanying drawings are non-limiting exemplary embodiments and that the scope of the present invention is defined solely by the claims. The features illustrated or described in connection with one exemplary embodiment may be combined with the features of other embodiments. Such modifications and variations are intended to be included within the scope of the present technology.

Disclosed herein are systems and methods for synthesis of nanoscale and microscale SCC material, such as NMC, using microwave plasma processing. Single crystal materials described herein may include lithiated transition metal oxides generally, including spinels, layered NaFeO₂ structures, lithium nickel oxide (layered), and substituted lithium nickel oxides (NC, NA, NCM, NCA), with or without dopants, such as Mg, Mn, Ti, Zr, Fe, Nb, Ca, K and Na. Single crystals are conventionally synthesized by a combination of co-precipitation, long calcination, and post-processing on a small scale. Co-precipitation based methods require multiple lengthy steps, consume a large amount of water to wash the precipitate, and generate a large amount of waste. The washing is performed multiple times to remove unwanted materials, such as sodium and sulfur that are present in the co-precipitation liquid precursor chemistry. In addition, co-precipitation produces materials that do not contain lithium, which is added in an additional step after the co-precipitate product is washed and dried. In addition, it may be difficult to add particular dopants to the material. This method relies on lithium diffusing into the co-precipitate product during a calcination step and requires relatively high temperatures and long calcination time to allow diffusion of lithium into the bulk. Further, the processing can take multiple days from start to final product, the solid precipitate. Also, the solid precursor produced through co-precipitation method does not contain lithium and necessitates an additional lithiation step by adding a lithium compound to the precursor and further calcining the mixture at the right temperature. The process of incorporating lithium into the precursor material happens through diffusion of lithium into the bulk of the precursor particles. This necessitates high temperatures (700° C.-1000° C.) and a long calcining time of about 10 hours or more.

According to the embodiments herein, SCC materials may be synthesized without co-precipitation, with a lower calcination time, and on a large scale. Some embodiments herein include methods of preparing SCC powders for use in a cathode of a lithium-ion cell, the method comprising providing raw materials of metallic salts comprising lithium dissolved in a solvent, mixing the raw materials to form a feedstock material, and microwave plasma processing the feedstock material to produce a microscale or smaller sized SCC powder. The produced solid powder may have all or part of NMC constituent materials. In some embodiments, no thermal post-processing is performed after the microwave plasma processing. In some embodiments, the SCC can have reduced contaminants or be contamination-free. Furthermore, the SCC can be significantly cheaper and faster to produce than that produced by standard co-precipitation, reducing costs of production, and microwave plasma processing can eliminate the need for the utilization of large amounts of water. In some embodiments, any of the methods disclosed herein do not require one or more of co-precipitation, filtering, or washing/drying. Further, in some embodiments, the methods do not require lithium to be added to any powder as a separate step requiring subsequent thermal processing. In some embodiments, calcination is not required, though other embodiments may use calcination.

The methods disclosed herein can produce nano or micron sized SCC powder (such as single-crystal NMC powder) which can be completed on a time scale of hours, rather than days. Specifically, the process may be used to synthesize single-crystal lithium containing transition metal oxides to be made in minimized processing steps by introducing liquid or solid precursor into a microwave plasma process, wherein a microwave-generated plasma, transforms the precursor into a crystallized material with the appropriate single-crystal structure, as defined by the chemistry and x-ray diffraction analysis, with or without the need for thermal post processing after microwave plasma processing, such as calcining. Furthermore, significant differences exist between the microwave plasma apparatuses described herein and other plasma generation torches, such as induction plasma. For example, microwave plasma is hotter on the interior of the plasma plume, while induction is hotter on the outside of the plumes. In particular, the outer region of an induction plasma can reach about 10,000 K while the inside processing region may only reach about 1,000 K. This large temperature difference leads to processing and feeding problems

Some embodiments herein are directed to systems and methods for using microwave plasma processing to synthesize advanced, ultra-high Ni, single crystal cathode (SCC) production, overcoming the existing issues with processing such materials. Microwave plasma processing of these SCC materials provides a low cost, scalable approach. In some embodiments, advanced SCC materials may be synthesized through microwave plasma processing of feedstock materials, wherein the SCC materials may comprise at least 80% nickel. In some embodiments, the microwave plasma processing may enable synthesis of SCC materials with very short calcinations.

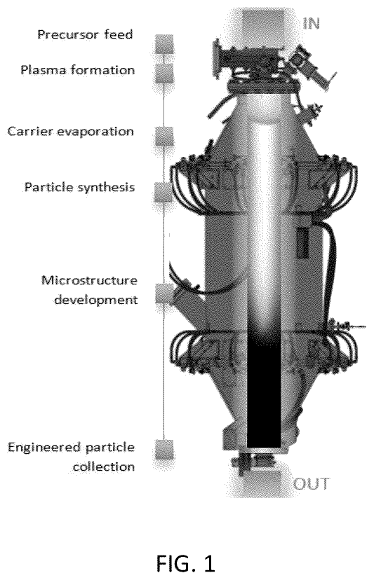

In some embodiments, the microwave plasma processing may be provided by microwave plasma processing apparatus comprising a microwave generator, waveguide, material feed system capable of feeding both liquid and solid feedstocks, a reactor containing a plasma generation zone, a reaction zone, a post reaction thermal profile zone, multiple gas feeds to control plasma reaction zone parameters and thermal profiles, and a material collection system. A system schematic of an example microwave plasma processing apparatus is illustrated in FIG. 1. As illustrated, the apparatus may comprise a precursor/feedstock feed in the form of a hopper or nebulizer to receive input of solid or liquid feedstock into the plasma processing apparatus. In some embodiments, the feedstock may be inputted with one or more carrier liquids. Feedstock comprising all necessary elements for the desired product may be fed into the plasma. For example, the feedstock may comprise all or part of the NMC constituent materials.

In some embodiments, the feedstock may comprise aqueous solutions of salts, providing tremendous flexibility in formulation chemistry and dopants. In some embodiments, the salts may comprise metallic salts comprising lithium, nickel, manganese, cobalt, or combinations thereof. Metallic salts can include, but are not limited to, acetates, bromides, carbonates, chlorates, chlorides, fluorides, formates, hydroxides, iodides, nitrates, nitrites, oxalates, oxides, perchlorates, sulfates, carboxylates, phosphates, nitrates, and oxynitrates. The metallic salts can be dissolved and mixed/stirred in an appropriate solvent such as water (for example deionized water), various alcohols, ethanol, methanol, xylene, organic solvents, or blends of solvents, or alternatively, dispersing insoluble or partially soluble powders in an appropriate medium to form a liquid precursor. In some embodiments, a pH of the liquid precursor can be controlled within a range of 1-14 with metal-free strong acids and bases such as nitric acid or ammonium hydroxide. Solid powder feedstock composed of a solid solution or mixture with a particular overall composition can also be prepared separately and used as a solid feedstock. The temperature, pH, and composition of the solvent can dictate the amount of metallic salt that can be dissolved in the solvent and therefore the throughput of the process.

The quantity of each salt/solid to be dissolved/dispersed can be calculated to give a desired final stoichiometry of the SCC (e.g., NMC) material to be made. As an example, if making NMC 622, the amount of lithium salt would be calculated to yield one mole of lithium, the amount of nickel salt would be calculated to yield 0.6 mole of nickel, the amount of manganese salt would be calculated to yield 0.2 mole of manganese, and the amount of cobalt salt would be calculated to yield 0.2 mole of cobalt in the final NMC 622 product. However, in some instances, the amount of any of the salts/solids to be dissolved/dispersed can be increased beyond the theoretical amount calculated. In some instances, lithium, manganese, or other transition metals or constituent elements, may be vaporized during microwave plasma processing and yield less of the metal in the final product than theoretically calculated. Increasing the amount of the salt/solid in the precursor solution/dispersion may compensate for the vaporized metal to reach the final desired stoichiometry. The salt solutions/solid dispersions can be well stirred and filtered if necessary to produce a clean solution, free of any sediments. Additive chemicals such as ethanol, citric acid, acetic acid, formic acid, and others may be added to control morphology, and chemical reactions.

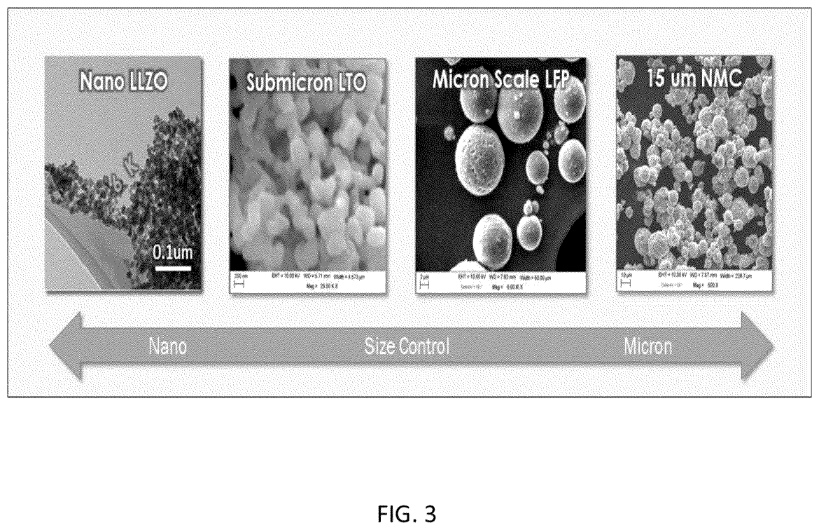

In some embodiments, the apparatus may comprise a microwave plasma formation or generation zone, wherein a gas is exposed to microwaves generated by a microwave generator, such that the gas is ionized and forms a microwave plasma. A stable and uniform microwave plasma is formed using a gas appropriate to the product chemistry (e.g., oxygen, nitrogen, argon, etc.). In some embodiments, within or downstream of the microwave plasma generation zone, the feedstock and the optional carrier liquid may be exposed to the plasma, wherein the carrier liquid may be evaporated, and the feedstock may undergo physical and/or chemical reactions when exposed to the plasma. Any carrier liquids may be quickly evaporated, and the intimately mixed precursor may react to form the desired compound, aided by the temperature and reactivity of the plasma. As material passes farther down the plasma processing apparatus, the microstructure is developed, controlled by the length and temperature profile of this region. Parameters within the plasma processing apparatus, such as the temperature, pressure, and feedstock residence time, among others, may be altered to achieve a desired material upon exposure to the plasma. For example, control of feedstock droplet size, reaction atmosphere, plasma power, feedstock residence times, and precursor chemistry enable control over particle size, morphology, and microstructure of the desired product. In some embodiments, after exposure to the plasma, the product is collected either in cyclones or a baghouse depending on the desired product particle size. In some embodiments, the process takes less than 2 seconds, has a small apparatus footprint, and results in very low conversion costs. In some embodiments, the collected product may be calcined at a predetermined temperature for a predetermined time period to form SCC electroactive material with all the desired elemental constituents and the desired crystallographic structure. In some embodiments, calcining is not needed to form the electroactive materials. The flexibility of the plasma processing technology is demonstrated in FIG. 3, which contains a sampling of the battery materials and particle sizes that may be produced.

Specifically, disclosed herein are methods, systems, and apparatuses for producing lithium-containing particles and Li-ion battery materials. Cathode materials for Li-ion batteries can include, for example, lithium-containing transition metal oxides, such as, for example, LiNiₓMn_{y}Co_{z}O₂ (NMC), wherein x+y+z equals 1 (or about 1).

Various characteristics of the final SCC powder particles, such as porosity, particle size, particle size distribution, phase composition and purity, microstructure, etc. can be tailored and controlled by fine tuning various process parameters and input materials. In some embodiments, these can include precursor solution chemistry, droplet size, plasma gas flow rates, plasma process gas choice, residence time of the droplets within the plasma, quenching rate, power density of the plasma, etc. These process parameters can be tailored, in some embodiments, to produce micron and/or sub-micron scale particles with tailored surface area, a specific porosity level, low-resistance Li-ion diffusion pathway, a narrow size distribution of about +2%, and containing a micro- or nano-grain microstructure.

The feedstock material, either liquid or solid, can be introduced into a plasma for processing. U.S. Pat. Pub. No. 2018/0297122, U.S. Pat. No. 8,748,785 B2, and U.S. Pat. No. 9,932,673 B2 disclose certain processing techniques that can be used in the disclosed process, specifically for microwave plasma processing. Accordingly, U.S. Pat. Pub. No. 2018/0297122, U.S. Pat. No. 8,748,785 B2, and U.S. Pat. No. 9,932,673 B2 are incorporated by reference in their entirety and the techniques describes should be considered to be applicable to the feedstock described herein. The plasma can include, for example, a microwave generated plasma with a substantially uniform temperature profile.

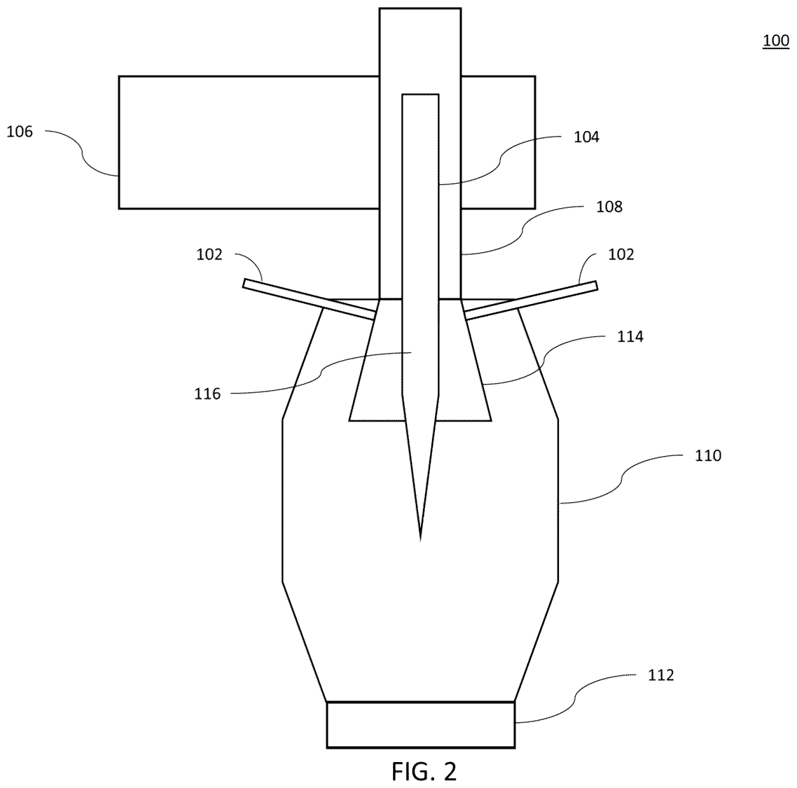

FIG. 2 illustrates another exemplary microwave plasma torch apparatus 100 that can be used in the production of SCC materials, according to some embodiments herein. As discussed above, in some embodiments, a feedstock can be introduced, via one or more feedstock inlets 102, into a microwave generated plasma 104. In some embodiments, an entrainment gas flow and/or a sheath flow may be injected into the microwave plasma torch 100 to create flow conditions within the plasma torch prior to ignition of the plasma 104 via microwave radiation source 106. In some embodiments, a microwave plasma torch may include a side-feeding hopper or nebulizer rather than the top feeding hopper or nebulizer shown in the embodiment of FIG. 1, thus allowing for downstream feeding. Thus, in a side-feeding implementation, the feedstock may be injected after the microwave plasma torch applicator for processing in the “plume” or “exhaust” of the microwave plasma torch. Thus, the plasma of the microwave plasma torch may be engaged at the exit end of the plasma torch to allow downstream feeding of the feedstock, as opposed to the top-feeding (or upstream feeding) configuration. Other feeding configurations may include one or several individual feeding nozzles surrounding the plasma plume. The feedstock powder or spray can enter the plasma from any direction and can be fed in 360° around the plasma. The feedstock powder can enter the plasma at a specific position along the length of the plasma plume, such as hot zone where a specific temperature has been measured and a residence time estimated for sufficient reaction of the particles. The reacted particles exit the plasma into a sealed chamber where they are quenched then collected. In some embodiments, the plasma of the microwave plasma torch is engaged at the exit end of the plasma torch core tube 108, or further downstream. In some embodiments, adjustable downstream feeding allows engaging the feedstock with the plasma plume downstream at a temperature suitable for optimal melting of feedstock through precise targeting of temperature level and residence time. Adjusting the inlet location and plasma characteristics may allow for further customization of material characteristics. Furthermore, in some embodiments, by adjusting power, gas flow rates, pressure, and equipment configuration (e.g., introducing an extension tube), the length of the plasma plume may be adjusted. Furthermore, the feedstock may enter the plasma at a specific position along the length of the plasma 104 by adjusting placement of the inlets 102, where a specific temperature has been measured and a residence time estimated for providing the desirable characteristics of the resulting material.

In some embodiments, an entrainment gas flow, and a sheath flow (downward arrows) may be injected through inlets to create flow conditions within the plasma torch prior to ignition of the plasma via microwave radiation source 106. In some embodiments, the entrainment flow and sheath flow are both axis-symmetric and laminar, while in other embodiments the gas flows are swirling. In some embodiments, the feedstock may be introduced into the microwave plasma torch 100, where the feedstock may be entrained by a gas flow that directs the materials toward the plasma 104.

Although the gases described above may be used, it is to be understood that a variety of gases can be used depending on the desired material and processing conditions. In some embodiments, within the microwave plasma 104, the feedstock may undergo a physical and/or chemical transformation. Inlets 102 can be used to introduce process gases to entrain and accelerate the feedstock towards plasma 104. In some embodiments, a second gas flow can be created to provide sheathing for the inside wall of a core gas tube 108 and a reaction chamber 110 to protect those structures from melting due to heat radiation from plasma 104.

The feed materials may be introduced axially or otherwise into the microwave plasma torch, where they are entrained by a gas flow that directs the materials toward the plasma. Within the microwave-generated plasma, the feed materials are reacted in order to synthesize the product and chemical reactions between the feedstock and reactive plasma gases may occur. Inlets can be used to introduce process gases to entrain and accelerate particles axis towards plasma 104.

Feedstock material particles may be accelerated by entrainment using a core laminar gas flow created through an annular gap within the plasma torch. A second laminar flow can be created through a second annular gap to provide laminar sheathing for the inside wall of the plasma torch to protect it from melting due to heat radiation from plasma 104. In some embodiments, the laminar flows direct particles toward the plasma 104 along a path as close as possible to the central axis of the torch, exposing them to a uniform temperature within the plasma. In some embodiments, suitable flow conditions are present to keep the particles from reaching the inner wall of the plasma torch where plasma attachment could take place. In some embodiments, the particles are guided by the gas flows towards microwave plasma 104 were each undergoes homogeneous thermal treatment.

In some embodiments, implementation of the downstream injection method may use a downstream swirl or quenching. A downstream swirl refers to an additional swirl component that can be introduced downstream from the plasma torch to keep the powder from the walls of the core tube 108, the reactor chamber 110, and/or an extension tube 114.

Various parameters of the microwave plasma 104 may be adjusted manually or automatically in order to achieve a desired material. These parameters may include, for example, power, plasma gas flow rates, type of plasma gas, presence of an extension tube, extension tube material, level of insulation of the reactor chamber or the extension tube, level of coating of the extension tube, geometry of the extension tube (e.g. tapered/stepped), feed material size, feed material insertion rate, feed material inlet location, feed material inlet orientation, number of feed material inlets, plasma temperature, residence time and cooling rates. The resulting material may exit the plasma into a sealed chamber 112 where the material is quenched then collected.

FIG. 3 illustrates examples of chemistries and size flexibility of plasma processing systems for lithium-ion/solid state chemistries according to some embodiments herein. For the synthesis of NMC cathode materials, microwave plasma processing may enable a significant conversion-cost reduction relative to the standard co-precipitation and calcination approach typically used. The efficiency increase of plasma processing may be a result of reduced process steps, reduced energy consumption through, for example, eliminating the 10+hour calcination step (required because lithium cannot be included in the co-precipitation precursor), and eliminating waste generation. In some embodiments, a short heat treatment step may be used for SCC material, which may be between about 1 hour and about 5 hours. However, this heat treatment step is significantly shorter than the additional steps required for producing SCC NMC using standard methods.

In some embodiments, a SCC synthesis may comprise atomizing an aqueous salt solution containing Ni, Mn, Co, and Li and delivering the atomized salt solution to the microwave plasma processing apparatus. In some embodiments, the atomized salt solution may form droplets prior to or upon exposure to the microwave plasma. Initially droplets may be formed prior to introduction to the plasma through an atomizing technology (gas nebulization, ultrasonic atomization, piezo droplet mechanisms, etc.). Droplets may also be generated via secondary atomization (explosive or turbulence induced) prior to or within the plasma splitting individual fed droplets and/or liquid streams. Without being bound by theory, in some embodiments, the droplets rapidly form a mixture of disordered, but uniform, lithium transition metal oxides with the lithium salt.

In some embodiments, a feedstock for use in a SCC synthesis method as described herein may comprise Li, Ni, Mn, and cobalt salts, such as nitrate salts, dissolved in a solvent, such as water. In other embodiments, a feedstock may comprise Li, Ni, Mn, and cobalt nitrate or acetate salts dissolved in a solvent, such as water. In other embodiments, a feedstock may comprise a Li source, nickel oxide, manganese oxide, and cobalt oxide. In some embodiments, the feedstock may be spray dried to solidify the feedstock prior to providing the feedstock to the microwave plasma processing apparatus. In some embodiments, the feedstock may be optionally dried or solidified prior to microwave plasma processing. In some embodiments, the liquid or solid feedstock is provided to the microwave plasma processing apparatus through, for example, a top-feeding or side-feeding hopper or nebulizer. In some embodiments, carrier solvents and/or hydrates are removed to leave the reactants (if necessary) followed by pyrolysis. In some embodiments, the feedstock may not be completely vaporized, and instead may be dried/consolidated, possibly dehydrated, and then reacted directly, and/or reacted to form the finished particles. In some embodiments, an additional step of spray drying, shown can be performed prior to incorporating the feedstock material into the microwave plasma. Thus, a solid feedstock can be introduced into the microwave plasma, rather than a liquid. A salt solution or dispersion can be spray dried to produce a solid feedstock with particles in the correct size range for the target finished powder. In some embodiments, the solid feedstock powder is crystallized during microwave plasma processing.

In some embodiments, the collected product of plasma processing may comprise solid precursors of SCC material. These solid precursors may have an identical composition as the SCC powder material. However, the solid precursors of SCC material may be non-crystallized, partially crystallized, or partially formed materials. In some embodiments, the precursors of SCC material may comprise inhomogeneous material with lithiated metal oxides and unreacted lithium nitrate intimate with one another in very small clumps. Once plasma processed, the powder material can be nanoparticles or micron sized particles. In some embodiments, the nanoparticles can have a diameter of less than about 900 nm, about 800 nm, about 700 nm, about 600 nm, about 500 nm, about 400 nm, about 300 nm, about 200 nm or about 100 nm. In some embodiments, the nanoparticles can have a diameter of greater than about 100 nm, about 200 nm, about 300 nm, or about 400 nm. In some embodiments, the micron-sized particles can be between about 0.5 μm and about 50 μm. In some embodiments, the micron-sized particles can be between about 0.5 μm and about 30 μm. In some embodiments, when the precursors of SCC material are heated or calcined, the material crystallizes quickly

In some embodiments, the resulting material (e.g., NMCs) from the plasma processing of the solution precursor can be a single crystal material or a solid precursor of SCC material depending on the process conditions. In some embodiments, the resulting solid precursor of SCC material has a disordered but layered NMC structure. In some embodiments, the resulting solid precursor of SCC material has a disordered but non-layered structure. Furthermore, engineered interconnected internal porosity can be created in the solid precursor of SCC material with the proper selection of starting materials and process conditions. Generally, engineered interconnected internal porosity can be defined as empty space within the material exhibiting an open path through the particle surface. In some embodiments, at least a portion of the lithium of the feedstock may have not reacted and remains in the solid precursor of SCC material as lithium nitrate, which may fill the pores of the solid precursor of SCC. For example, in some embodiments, about 50% of the lithium in the feedstock may not react to leave lithium nitrate in the solid precursor of SCC.

If given enough time in the hot zone, the plasma-processed particles produced may be a single-crystal material. However, if quenched early, the material can be amorphous and further post processing may be required to produce the desired single crystal phase. Specifically, when the plasma length and temperature are sufficient to provide particles with the time and temperature necessary for atoms sufficient time to migrate to their preferred crystallographic locations, then a crystalline material is produced. The length of the plasma can be tuned with parameters such as power, torch diameter, reactor length, gas flow rates, gas flow characteristics and torch type.

In some embodiments, the solid precursor of SCC may undergo a post-plasma processing. In some embodiments, materials may undergo a calcination process at a particular temperature and time to produce an SCC material. The calcination process may be undergone for about 0.25 hours to about 10 hours at a temperature between about 650° C. and 1000° C. in an atmosphere of about 1% to about 100% oxygen in nitrogen gas. In some embodiments, the post-calcination process may crystalize the solid precursor of SCC to form SCC. In some embodiments, a deagglomeration step may be performed after calcination in order to deagglomerate the SCC particles to form a single crystal powder. Sizing and classification may be done with, for example, air mill classification, ball milling, vibratory sieving, or jet mill classification. In some embodiments, if process conditions are optimal, a deagglomerated SCC material may be formed from the calcination process without agglomeration.

In some embodiments, the process involves introducing feedstock to a plasma at an appropriate feed rate and plasma power and gas type to initiate crystallization in the feedstock and subsequent complete evaporation of any solvent. In some embodiments, the SCC material may comprise NMC 811. In some embodiments, the final SCC material product comprises a granular powder, as opposed to a fused brick, and a standard deagglomeration step is sufficient to produce the free single crystals. Without being limited to any specific theory, it is believed that the nature of the intimately mixed precursor used in the plasma processing enables both a short calcination and the low degree of fusion within the product powder bed. In some embodiments, these same process properties facilitate synthesis of high and ultra-high nickel formulations of both NCA and NMC with significantly reduced cobalt and incorporation of dopants, such as Mg and Al without formation of separate phases.

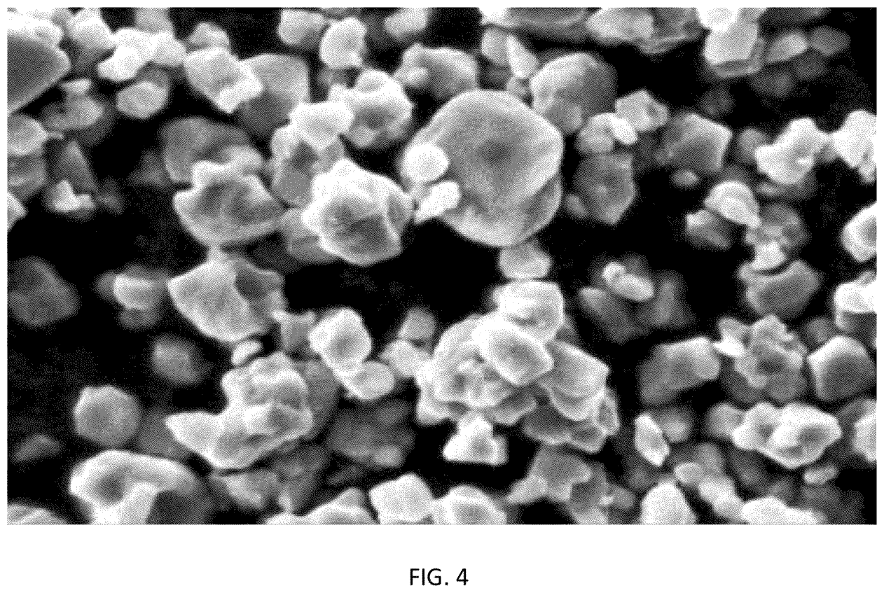

In some embodiments, the plasma processing described above may synthesize high or ultra-high nickel SCC materials offering step improvements in both energy via capacity improvements and cycle life and safety via the single crystal morphology relative to polycrystalline materials. FIG. 4 illustrates a microscopic image of an example NMC powder morphology synthesized according to the embodiments herein.

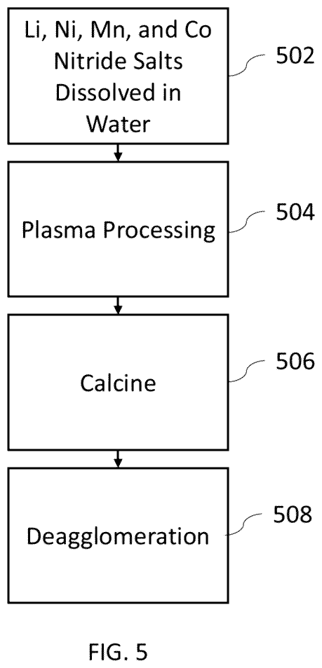

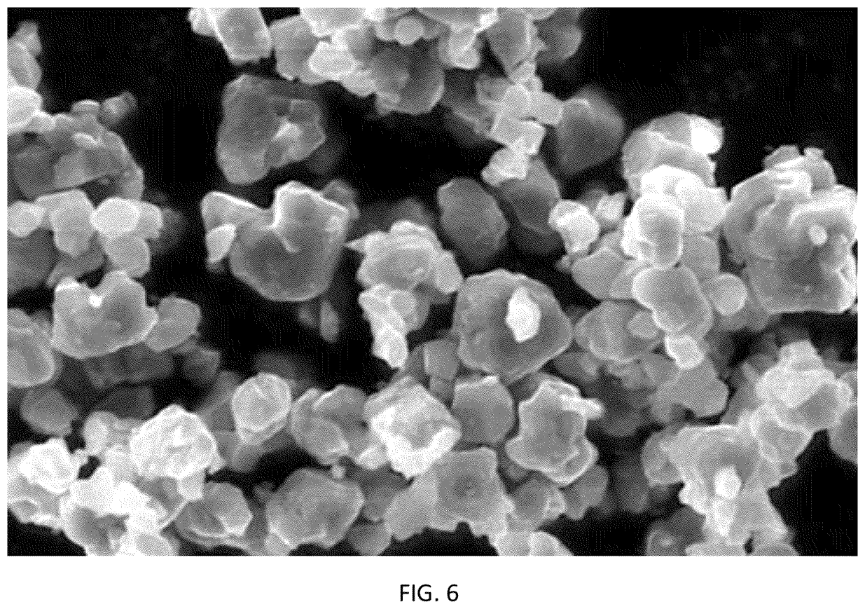

FIG. 5 illustrates an example flowchart of a process for producing a SCC material according to some embodiments described herein. In some embodiments, at 502, a feedstock may be provided, the feedstock comprising a Li, Ni, Mn, and cobalt nitrate salts dissolved in a solvent, such as water. In some embodiments, at 504, the liquid feedstock may be provided to a plasma processing apparatus for exposing the feedstock to a microwave plasma. Upon exposing the feedstock to plasma, the feedstock may form a solid precursor of SCC. In some embodiments, at 506, the solid precursor of SCC may be calcined to form an agglomerated SCC material. In some embodiments, at 508, the agglomerated SCC material may undergo a deagglomeration process to produce an SCC powder. FIG. 6 illustrates a microscopic image of another example NMC powder morphology synthesized according to the process of FIG. 5.

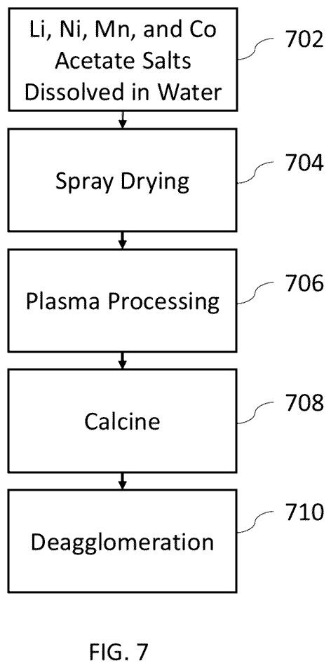

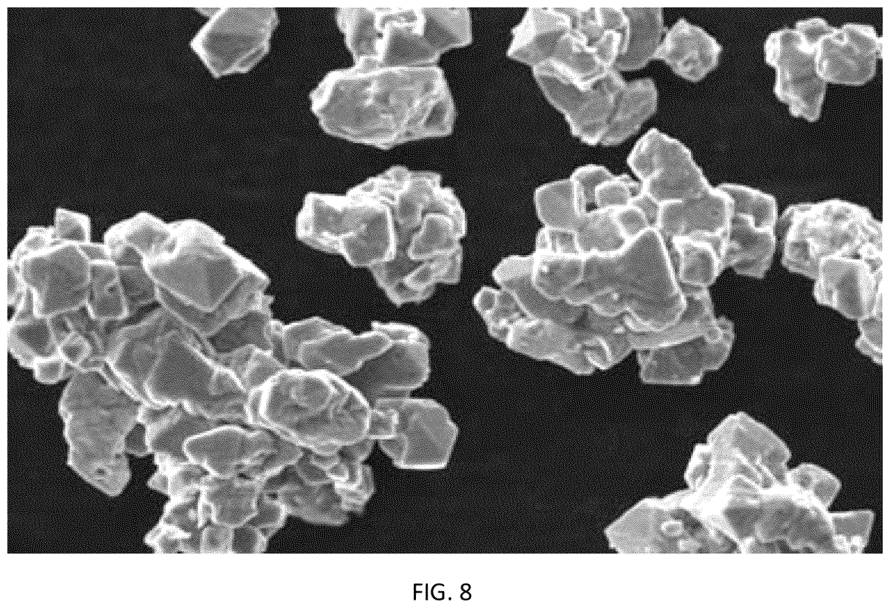

FIG. 7 illustrates an example flowchart of another process for producing a SCC material according to some embodiments described herein. In some embodiments, at 702, a feedstock may be provided, the feedstock comprising a Li, Ni, Mn, and cobalt acetate salts dissolved in a solvent, such as water. In some embodiments, at 704, the liquid feedstock may be spray dried to solidify the feedstock. In some embodiments, at 706, the solid feedstock may be provided to a plasma processing apparatus for exposing the feedstock to a microwave plasma. Upon exposing the feedstock to plasma, the feedstock may form a solid precursor of SCC. In some embodiments, at 708, the solid precursor of SCC may be calcined to form an agglomerated SCC material. In some embodiments, at 710, the agglomerated SCC material may undergo a deagglomeration process to produce an SCC powder. FIG. 8 illustrates a microscopic image of another example NMC powder morphology synthesized according to the embodiment of FIG. 7.

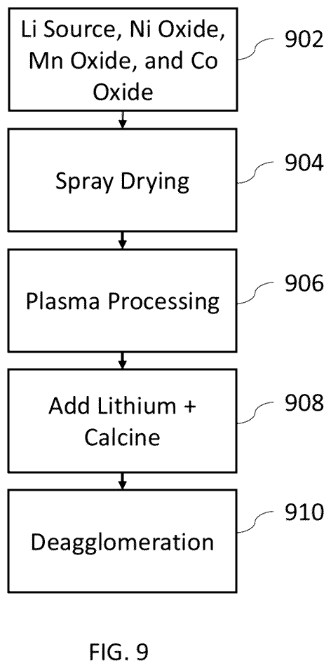

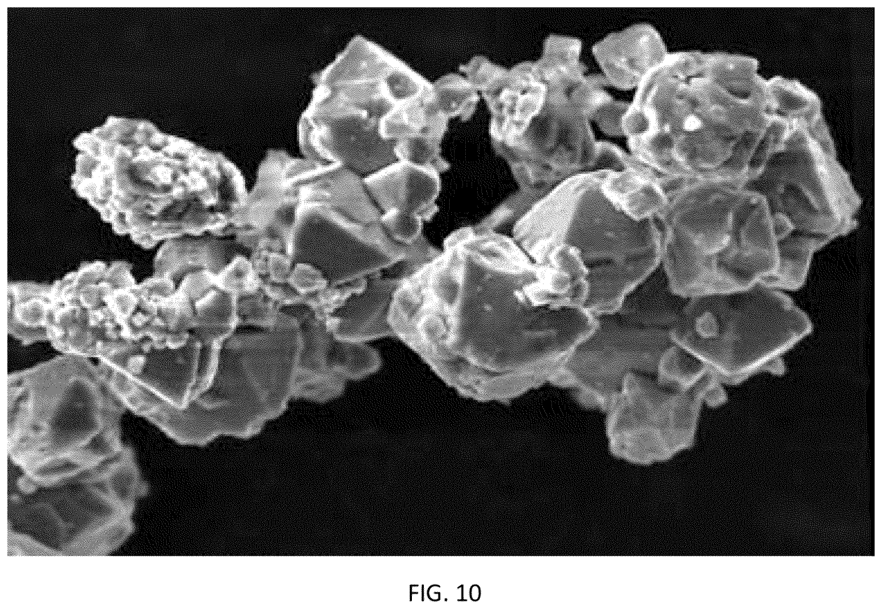

FIG. 9 illustrates an example flowchart of another process for producing a SCC material according to some embodiments described herein. In some embodiments, at 902, a feedstock may be provided, the feedstock comprising a Li source, Ni oxide, Mn oxide, and cobalt oxide. In some embodiments, at 904, the liquid feedstock may be spray dried to solidify the feedstock. In some embodiments, at 906, the solid feedstock may be provided to a plasma processing apparatus for exposing the feedstock to a microwave plasma. Upon exposing the feedstock to plasma, the feedstock may form a solid precursor of SCC. In some embodiments, at 908, the solid precursor of SCC may be calcined to form an agglomerated SCC material. Optionally, lithium may be added before or during calcination. In some embodiments, at 910, the agglomerated SCC material may undergo a deagglomeration process to produce an SCC powder. FIG. 10 illustrates a microscopic image of another example NMC powder morphology synthesized according to the embodiment of FIG. 9.

### Additional Embodiments

In the foregoing specification, the invention has been described with reference to specific embodiments thereof. It will, however, be evident that various modifications and changes may be made thereto without departing from the broader spirit and scope of the invention. The specification and drawings are, accordingly, to be regarded in an illustrative rather than restrictive sense.

Indeed, although this invention has been disclosed in the context of certain embodiments and examples, it will be understood by those skilled in the art that the invention extends beyond the specifically disclosed embodiments to other alternative embodiments and/or uses of the invention and obvious modifications and equivalents thereof. In addition, while several variations of the embodiments of the invention have been shown and described in detail, other modifications, which are within the scope of this invention, will be readily apparent to those of skill in the art based upon this disclosure. It is also contemplated that various combinations or sub-combinations of the specific features and aspects of the embodiments may be made and still fall within the scope of the invention. It should be understood that various features and aspects of the disclosed embodiments can be combined with, or substituted for, one another in order to form varying modes of the embodiments of the disclosed invention. Any methods disclosed herein need not be performed in the order recited. Thus, it is intended that the scope of the invention herein disclosed should not be limited by the particular embodiments described above.

It will be appreciated that the systems and methods of the disclosure each have several innovative aspects, no single one of which is solely responsible or required for the desirable attributes disclosed herein. The various features and processes described above may be used independently of one another or may be combined in various ways. All possible combinations and subcombinations are intended to fall within the scope of this disclosure.

Certain features that are described in this specification in the context of separate embodiments also may be implemented in combination in a single embodiment. Conversely, various features that are described in the context of a single embodiment also may be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination. No single feature or group of features is necessary or indispensable to each and every embodiment.

It will also be appreciated that conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. In addition, the term “or” is used in its inclusive sense (and not in its exclusive sense) so that when used, for example, to connect a list of elements, the term “or” means one, some, or all of the elements in the list. In addition, the articles “a,” “an,” and “the” as used in this application and the appended claims are to be construed to mean “one or more” or “at least one” unless specified otherwise. Similarly, while operations may be depicted in the drawings in a particular order, it is to be recognized that such operations need not be performed in the particular order shown or in sequential order, or that all illustrated operations be performed, to achieve desirable results. Further, the drawings may schematically depict one more example processes in the form of a flowchart. However, other operations that are not depicted may be incorporated in the example methods and processes that are schematically illustrated. For example, one or more additional operations may be performed before, after, simultaneously, or between any of the illustrated operations. Additionally, the operations may be rearranged or reordered in other embodiments. In certain circumstances, multitasking and parallel processing may be advantageous. Moreover, the separation of various system components in the embodiments described above should not be understood as requiring such separation in all embodiments, and it should be understood that the described program components and systems may generally be integrated together in a single software product or packaged into multiple software products. Additionally, other embodiments are within the scope of the following claims. In some cases, the actions recited in the claims may be performed in a different order and still achieve desirable results.

Further, while the methods and devices described herein may be susceptible to various modifications and alternative forms, specific examples thereof have been shown in the drawings and are herein described in detail. It should be understood, however, that the invention is not to be limited to the particular forms or methods disclosed, but, to the contrary, the invention is to cover all modifications, equivalents, and alternatives falling within the spirit and scope of the various implementations described and the appended claims. Further, the disclosure herein of any particular feature, aspect, method, property, characteristic, quality, attribute, element, or the like in connection with an implementation or embodiment can be used in all other implementations or embodiments set forth herein. Any methods disclosed herein need not be performed in the order recited. The methods disclosed herein may include certain actions taken by a practitioner; however, the methods can also include any third-party instruction of those actions, either expressly or by implication. The ranges disclosed herein also encompass any and all overlap, sub-ranges, and combinations thereof. Language such as “up to,” “at least,” “greater than,” “less than,” “between,” and the like includes the number recited. Numbers preceded by a term such as “about” or “approximately” include the recited numbers and should be interpreted based on the circumstances (e.g., as accurate as reasonably possible under the circumstances, for example ±5%, ±10%, ±15%, etc.). For example, “about 3.5 mm” includes “3.5 mm.” Phrases preceded by a term such as “substantially” include the recited phrase and should be interpreted based on the circumstances (e.g., as much as reasonably possible under the circumstances). For example, “substantially constant” includes “constant.” Unless stated otherwise, all measurements are at standard conditions including temperature and pressure.

As used herein, a phrase referring to “at least one of” a list of items refers to any combination of those items, including single members. As an example, “at least one of: A, B, or C” is intended to cover: A, B, C, A and B, A and C, B and C, and A, B, and C. Conjunctive language such as the phrase “at least one of X, Y and Z,” unless specifically stated otherwise, is otherwise understood with the context as used in general to convey that an item, term, etc. may be at least one of X, Y or Z. Thus, such conjunctive language is not generally intended to imply that certain embodiments require at least one of X, at least one of Y, and at least one of Z to each be present. The headings provided herein, if any, are for convenience only and do not necessarily affect the scope or meaning of the devices and methods disclosed herein.

Accordingly, the claims are not intended to be limited to the embodiments shown herein but are to be accorded the widest scope consistent with this disclosure, the principles and the novel features disclosed herein.

What is claimed is:

1. A method for synthesizing single-crystal lithium-ion cathode (SCC) material, the method comprising:
providing a solid or liquid feedstock, the feedstock comprising lithium and nickel;
introducing the feedstock into a microwave-generated plasma to produce a solid precursor of SCC material, wherein introducing the feedstock into the microwave-generated plasma comprises feeding the feedstock to the microwave-generated plasma downstream in a plume or exhaust of the microwave-generated plasma; and
calcining the solid precursor of SCC material to produce the SCC material,
wherein the solid precursor of SCC material comprises metal oxide and unreacted lithium nitrate.

2. The method of claim 1, wherein the SCC material comprises a lithium nickel cobalt manganese oxide (NMC) powder.

3. The method of claim 2, wherein the NMC powder comprises NMC-811.

4. The method of claim 2, wherein the NMC powder comprises at least 80% nickel by weight.

5. The method of claim 1, wherein the solid precursor of SCC material comprises NMC having pores filled with lithium nitrate.

6. The method of claim 1, wherein the feedstock comprises lithium, nickel, and cobalt nitrate or lithium, nickel, and cobalt acetate salts dissolved in water.

7. The method of claim 1, wherein the SCC material comprises an agglomerated SCC material and the method further comprises deagglomerating the agglomerated SCC material to produce SCC powder.

8. The method of claim 1, further comprising adding lithium or lithium salt to the solid precursor of SCC material prior to or during calcining the solid precursor of SCC material.

9. The method of claim 1, wherein lithium nitrate is located within pores of the precursor of SCC material.

10. The method of claim 1, wherein the solid precursor of SCC material is calcined for about 0.25 hours to about 10 hours at a temperature between about 650° C. and 1000° C.

11. The method of claim 1, wherein the solid precursor of SCC material comprising metal oxide and unreacted lithium nitrate comprises inhomogeneous material with lithiated metal oxides and unreacted lithium nitrate intimate with one another in clumps.

12. The method of claim 11, wherein the clumps comprise nanoparticles.

13. The method of claim 12, wherein the nanoparticles have diameters of less than about 900 nm.

14. The method of claim 1, wherein the solid precursor of SCC material comprises a disordered but layered NMC structure.

15. The method of claim 1, wherein the solid precursor of SCC material comprises a disordered but non-layered structure.

16. The method of claim 5, wherein the majority of lithium in the feedstock does not react to leave lithium nitrate in the solid precursor of SCC.
